(19) United States
(12) Patent Application Publication
(10) Pub. No.: US 2010/0095882 A1
(43) Pub. Date: Apr. 22, 2010

(54) REACTOR DESIGN FOR GROWING GROUP III NITRIDE CRYSTALS AND METHOD OF GROWING GROUP III NITRIDE CRYSTALS

(76) Inventors: Tadao Hashimoto, Santa Barbara, CA (US); Masanori Ikari, Santa Barbara, CA (US); Edward Letts, Buellton, CA (US)

Correspondence Address: K&L Gates LLP;IP Docketing, 630 HANSEN WAY, PALO ALTO, CA, 94304, US

(21) Appl. No.: 12/580,849

(22) Filed: Oct. 16, 2009

Related U.S. Application Data
(60) Provisional application No. 61/106,110, filed on Oct. 16, 2008.

(51) Int. Cl. C30B 7/10; B01J 3/04

(52) U.S. Cl. 117/71; 117/224

(57) ABSTRACT

The present disclosure proves for new design of reactors used for ammonothermal growth of III nitride crystals. The reactors include a region intermediate a source dissolution region and a crystal growth region configured to provide growth of high quality crystals at rates greater than 100 μm/day. In one embodiment, multiple baffle plates having openings whose location is designed so that there is no direct path through the intermediate region, or with multiple baffle plates having differently sized openings on each plate so that the flow is slowed down and/or exhibit greater mixing are described. The disclosed designs enables obtaining high temperature difference between the dissolution region and the crystallization region without decreasing conductance through the device.

### CROSS REFERENCE TO RELATED APPLICATIONS

This application claims priority under 35 U.S.C. §119 to U.S. Provisional Application Ser. No. 61/106,110, filed Oct. 16, 2008, the disclosure of which is incorporated in its entirety by this reference. This application is further related to the following U.S. patent applications:

PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE”;

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS”;

U.S. Utility Patent Application Ser. No. 60/973,602 , filed on Sep. 19, 2007, by Tadao Hashimoto and Shuji Nakamura, entitled “GALLIUM NITRIDE BULK CRYSTALS AND THEIR GROWTH METHOD”;

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY”;

U.S. Utility Patent Application Ser. No. 61/067,117, filed on Feb. 25, 2008, by Tadao Hashimoto, Edward Letts, Masanori Ikari, entitled “METHOD FOR PRODUCING GROUP III-NITRIDE WAFERS AND GROUP III-NITRIDE WAFERS”;

U.S. Utility Patent Application Ser. No. 61/058,900, filed on Jun. 4, 2008, by Edward Letts, Tadao Hashimoto, Masanori Ikari, entitled “METHODS FOR PRODUCING IMPROVED CRYSTALLINITY GROUP III-NITRIDE CRYSTALS FROM INITIAL GROUP III-NITRIDE SEED BY AMMONOTHERMAL GROWTH”;

U.S. Utility Patent Application Ser. No. 61/058,910, filed on Jun. 4, 2008, by Tadao Hashimoto, Edward Letts, Masanori Ikari, entitled “HIGH-PRESSURE VESSEL FOR GROWING GROUP III NITRIDE CRYSTALS AND METHOD OF GROWING GROUP III NITRIDE CRYSTALS USING HIGH-PRESSURE VESSEL AND GROUP III NITRIDE CRYSTAL”;

U.S. Utility Patent Application Ser. No. 61/131,917, filed on Jun. 12, 2008, by Tadao Hashimoto, Masanori Ikari, Edward Letts, entitled “METHOD FOR TESTING III-NITRIDE WAFERS AND III-NITRIDE WAFERS WITH TEST DATA”;

PCT Application Serial No. PCT/US09/61022, filed Oct. 16, 2009, by Tadao Hashimoto, Masanori Ikari, Edward Letts, entitled: “REACTOR DESIGN FOR GROWING GROUP III NITRIDE CRYSTALS AND METHOD OF GROWING GROUP III NITRIDE CRYSTALS”, attorney docket no SIXPOI-004WO;

which applications are incorporated in their entirety by reference herein.

### BACKGROUND

1. Field of the Invention

The invention is related to a device and high-pressure reactor vessels used to grow group III nitride crystals expressed as BₓAl_{y}Ga_{z}In_{1-x-y-z}N(0≦x,y,z≦1) such as gallium nitride (GaN), boron nitride (BN), indium nitride (InN), aluminum nitride (AlN), and their solid solutions in high-pressure ammonia. The invention is also related to the methods of growing group III nitride crystals.

2. Description of the Existing Technology

GaN and its related group III alloys are the key material for various opto-electronic and electronic devices such as light emitting diodes (LEDs), laser diodes (LDs), microwave power transistors, and solar-blind photo detectors. Currently LEDs are widely used in cell phones, indicators, displays, and LDs are used in data storage disk drives. However, the majority of these devices are grown epitaxially on heterogeneous substrates, such as sapphire and silicon carbide since GaN wafers are extremely expensive compared to these heteroepitaxial substrates. The heteroepitaxial growth of group III-nitride causes highly defected or even cracked films, which hinders the realization of high-end optical and electronic devices, such as high-brightness LEDs for general lighting or high-power microwave transistors.

To solve all fundamental problems caused by heteroepitaxy, it is indispensable to utilize single crystalline group III nitride wafers sliced from bulk group III nitride crystal ingots. For the majority of devices, single crystalline GaN wafers are favorable because it is relatively easy to control the conductivity of the wafer and GaN wafer will provide the smallest lattice/thermal mismatch with device layers. However, due to the high melting point and high nitrogen vapor pressure at elevated temperature, it has been difficult to grow GaN crystal ingots. Growth methods using molten Ga, such as high-pressure high-temperature synthesis (see, for example: S. Porowski, MRS Internet Journal of Nitride Semiconductor, Res. 4S1, (1999) G1.3; and T. Inoue, et al, Phys. Stat. Sol. (b), 223 (2001) p. 15) and sodium flux (see, for example: M. Aoki, et al., J. Cryst. Growth 242 (2002) p. 70; and T. Iwahashi, et al, J. Cryst Growth 253 (2003) p. 1) have been proposed to grow GaN crystals, nevertheless the crystal shape grown in molten Ga becomes a thin platelet because molten Ga has low solubility of nitrogen and a low diffusion coefficient of nitrogen.

The ammonothermal method, which is a solvothermal method using high-pressure ammonia as a solvent has demonstrated successful growth of bulk GaN (see, for example: T. Hashimoto, et al., Jpn. J. Appl. Phys. 46 (2007) L889; U.S. Pat. Nos. 6,656,615; 7,132,730; and 7,160,388; International Patent Publication Nos. WO 07008198 and WO 07117689; and U.S. application Ser. No. 11/784,339). This technique is able to grow large GaN crystal ingots, because high-pressure ammonia used as a fluid medium has a high solubility of source materials such as GaN polycrystals or metallic Ga, and high transport speed of dissolved precursors can be achieved. GaN has retrograde solubility in supercritical ammonobasic solutions (U.S. Pat. No. 6,656,615; D. Peters, J. Cryst. Growth, 104 (1990) 411; T. Hashimoto, et al, J. Cryst. Growth 275 (2005) e525; M. Callahan, et al., J. Mater. Sci. 41 (2006) 1399; and T. Hashimoto, et al., J. Cryst. Growth 305 (2007) 311). Also, the growth temperature is higher than 500° C., which is more than 100° C. higher than hydrothermal growth of quartz or zinc-oxide. Therefore, basic ammonothermal growth of group III nitride crystals differs in many aspects from other solvothermal methods such as hydrothermal growth of quarts and zinc oxide. Because of this difference, it is not straightforward to apply the solvothermal method to grow group III nitride crystals and more improvements are required to realize mass production of GaN wafers by the ammonothermal method.

One of the major problems which hinders the commercialization of the ammonothermal growth of GaN is poor structural quality for crystals grown at fast growth rate, or in other words, it is very challenging to grow GaN with high structural quality at fast growth rate (see, D. Ehrentraut, et al., J. Cryst. Growth 310 (2008) 3902). All references cited in this background section are incorporated herein by reference. Although growth rates as high as 180 μm/day have been achieved, the quality of crystal structure was not sufficient for commercial use. Considering this limitation, the present disclosure discloses a novel design of a device, reactor and methods which provide high quality group III nitride crystals at acceptable growth rates.

### SUMMARY OF THE INVENTION

The present invention discloses reactor designs for growing group III nitride crystals in supercritical ammonia in high-pressure ammonothermal reactor vessels and methods for growing group III nitride crystals, such as GaN crystals.

According to one embodiment, the present disclosure provides for a reactor for growing group III nitride crystals having a static mixing region. The reactor comprises a high pressure ammonothermal reactor vessel, a source dissolution region configured to contain a group III nutrient material, a crystal growth region configured to contain at least one group III nitride seed crystal, and a static mixing region between the source dissolution region and the crystal growth region. The static mixing region is configured to equilibrate a solution comprising a group III nitride and supercritical ammonia. The equilibrated solution has at least one of a more uniform concentration and a more uniform temperature compared to a solution in an otherwise identical reactor differing only in having an intermediate region in place of the static mixing region and comprising a plurality of plates, wherein each plate has a single opening of same size aligned along a longitudinal axis of the reactor.

According to another embodiment, the present disclosure provides for a reactor for growing group III nitride crystals having an intermediate heating region. The reactor comprises a high pressure ammonothermal reactor vessel, a source dissolution region configured to be externally heated at a first temperature and contain a group III nutrient material, a crystal growth region configured to be externally heated at a second temperature and contain at least one group III nitride seed crystal, and an intermediate heating region having at least one flow channel. The at least one flow channel of the heating region has a path-length for a fluid flowing through the intermediate heating region that is greater than a path-length of a flow channel parallel to a longitudinal axis of the reactor from the source dissolution region to the crystal growth region. The fluid flowing through the reactor comprises group III nitride and supercritical ammonia.

Still other embodiments of the present disclosure provide for a reactor for growing group III nitride crystals having a baffle region. The reactor comprises a high pressure ammonothermal reactor vessel, a source dissolution region configured to contain a group III nutrient material, a crystal growth region configured to contain at least one group III nitride seed crystal, and a baffle region between the source dissolution region and the crystal growth region. The baffle region comprises a plurality of plates oriented transverse to a flow comprising a group III nitride and supercritical ammonia from the source dissolution region to the crystal growth region. The plurality of plates comprise a first plate having one or more openings and a second plate having one or more openings different than the one or more openings of the first plate.

Further embodiments of the present disclosure provide for methods for growing group III nitride crystals having high quality. The method comprises passing a solution comprising group III nitride and supercritical ammonia through a baffle region comprising a plurality of flow impediments; and growing a group III nitride crystal in a crystal growth region. The flow impediments define a flow path for the solution having a path-length that is greater than a path-length of a flow path parallel to a longitudinal axis of the baffle region. The flow impediments may comprise a plurality of plates oriented transverse to the longitudinal axis of the baffle region.

In the case of ammonothermal growth of GaN, the following three steps occur; 1) dissolution of Ga containing nutrient such as polycrystalline GaN and/or metal Ga into supercritical ammonia in the source dissolution region; 2) transport of the dissolved source into the crystal growth or crystallization region; 3) crystal growth of GaN on single crystalline GaN seeds in the crystal growth region. These three steps are affected by the design of the reactor and the intermediate region placed between the source dissolution region and the crystal growth region. According to certain embodiment, the present description discloses novel designs of intermediate regions with multiple baffle plates having openings whose location is designed so that there is no direct or linear path through the region, or with multiple baffle plates having differently sized openings on each plate so that the flow is slowed down without decreasing the total amount of transport.

### BRIEF DESCRIPTION OF THE DRAWINGS

Referring now to the drawings in which like reference numbers represent corresponding parts throughout:

FIG. 1 illustrates a schematic drawing of one embodiments of the high-pressure reactor of the present disclosure.

FIG. 2 illustrates a conventional design of a baffle device. In the figure, 7a represents a baffle plate of conventional design.

FIG. 3 illustrates one embodiment of baffle device according to the present disclosure. In the figure, 7b represents a baffle plate with holes which do not make a direct straight path through the device 7.

FIG. 4 illustrates one embodiment of baffle device according to the present disclosure. In the figure, 7c represents a baffle plate with holes which include center hole of different diameter from that of 7a.

FIG. 5 illustrates one embodiment of baffle device according to the present disclosure. In the figure, 7d represents a baffle plate with a center hole of different diameter from that of 7a.

### DETAILED DESCRIPTION OF THE INVENTION

The present disclosure provides a reactor design for growing group III nitride crystals, such as, for example, GaN crystals, in an ammonothermal growth reactor (i.e. high-pressure vessel). The reactors allow for the rapid growth of group III nitride crystals having a high purity and quality, suitable for use in various opto-electronic and electronic devices, such as, but not limited to, light emitting diodes (LEDs), laser diodes (LDs), microwave power transistors, and solar-blind photo detectors. The high quality group III nitride crystals are grown at a rate of at least 100 μm/day, a rate at which prior art reactors cannot produce group III nitride crystals having the desired high quality. Also described is a novel baffle region for a ammonothermal growth reactor for growing group III nitride crystals. Methods for growing group III nitride crystals utilizing the reactor design are also described.

Other than the operating examples, or where otherwise indicated, all numbers expressing quantities of ingredients, processing conditions and the like used in the specification and claims are to be understood as being modified in all instances by the term “about”. Accordingly, unless indicated to the contrary, the numerical parameters set forth in the following specification and attached claims are approximations that may vary depending upon the desired properties sought to be obtained. At the very least, and not as an attempt to limit the application of the doctrine of equivalents to the scope of the claims, each numerical parameter should at least be construed in light of the number of reported significant digits and by applying ordinary rounding techniques.

Notwithstanding that the numerical ranges and parameters setting forth the broad scope of the disclosure are approximations, the numerical values set forth in the specific examples are reported as precisely as possible. Any numerical values, however, may contain certain errors, such as, for example, equipment and/or operator error, necessarily resulting from the standard deviation found in their respective testing measurements.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of less than or equal to 10.

Any patent, publication, or other disclosure material, in whole or in part, that is said to be incorporated by reference herein is incorporated herein only to the extent that the incorporated material does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

The present disclosure describes several different features and aspects of the invention with reference to various exemplary non-limiting embodiments. It is understood, however, that the invention embraces numerous alternative embodiments, which may be accomplished by combining any of the different features, aspects, and embodiments described herein in any combination that one of ordinary skill in the art would find useful.

Since GaN has retrograde solubility in ammonobasic solutions, the lower the temperature of the dissolution region, the more GaN is dissolved in the basic supercritical ammonia. However, the crystal quality (e.g. structural perfection and purity) tends to improve when the crystal is grown at higher temperature. Therefore, in certain embodiments it can often be helpful to maintain the temperature of the crystallization region at higher temperature while maintaining the temperature of the dissolution region at lower temperature. In other embodiments, the inventors have found that the external temperature of the crystal growth region may be set lower than the external temperature of the source dissolution region, while still producing acceptable high quality crystals.

In one embodiment, one way to attain this situation is to increase number of baffles or decreasing the perimeter of the opening of the baffle plates. However, if the conductance of the intermediate region, such as the baffle region, is simply decreased, the transport of source from the dissolution region to the crystallization region may be impeded, thus resulting in slow growth rate. In order to solve this problem, this present disclosure presents novel designs for a baffle region and high pressure ammonothermal reactors, which may act to slow down the flow without decreasing the overall conductance. In this way, the transit time of the fluid passing through the intermediate region may become greater and the concentration of the solubilized group III nitride more uniform and/or the temperature of the fluid flowing into the crystallization region may become more uniform and closer to that of the crystallization region. According to various embodiments described herein, one goal of the present reactor design is to attain zigzag-shaped or circuitous flow path or diverted flow path through the region intermediate to a source dissolution region and the crystal growth region.

According to various embodiments, the present disclosure provides for a reactor for growing group III nitride crystals. Suitable group III nitride crystals include, for example, boron nitride (BN), aluminum nitride (AlN), gallium nitride (GaN), and indium nitride (InN). According to specific embodiments, the group III nitride crystal may be a GaN crystal. The reactors are configured to produce group III nitride crystals, such as, for example, GaN crystals, having high quality and suitable for use in various opto-electronic and electronic devices. According to the embodiments described herein, the various embodiments of the reactor for growing group III nitride crystals comprise a high pressure ammonothermal reactor vessel, a source dissolution region, a crystal growth region and a region intermediate the source dissolution region and the crystal growth region. According to certain embodiments, the intermediate region may comprise a static mixing region, whereas in other embodiments, the intermediate region may comprise an intermediate heating region and/or a baffle region. According to other non-limiting embodiments, the intermediate region may incorporate features comprising one or more of a static mixing region, a heating region, and a baffle region.

In the various embodiments of the reactors for growing group III nitride crystals, the reactors comprise a high pressure ammonothermal reactor vessel. The high pressure ammonothermal reactor vessel is configured to withstand the high temperatures and pressures necessary to contain supercritical ammonia in an ammonothermal process. For example, the ammonothermal reactor vessel must withstand temperatures of up to 600° C. and pressures of up to 300 megapascal (MPa). The high pressure ammonothermal reactor vessel may be configured to contain the various components necessary for the ammonothermal growth of group III nitride crystals. For example, the reactor vessel may be configured to comprise a source dissolution region, a crystal growth region, and an intermediate region, as set forth in the various embodiments described herein.

According to various embodiments, the reactors according the present disclosure comprise a source dissolution region. The source dissolution region may be configured to contain a group III nutrient material. The source dissolution region may be the portion of the reactor where the nutrient material is dissolved or otherwise solubilized in the supercritical ammonia. For example, in certain embodiments, the source dissolution region may be configured to contain a mesh basket or other containment apparatus made from nickel, a nickel alloy or other inert material for holding the nutrient material in the source dissolution region. Examples of nutrient materials may include a group III source material, for example, polycrystalline group III nitride materials or solid allotropes of the group III material (such as, solid boron, metallic aluminum, metallic gallium, or metallic indium), or other nutrient material that may dissolve in the supercritical ammonia solution and provide a solution of group III nitride. In those embodiments involving GaN, the nutrient material may comprise metallic Ga, polycrystalline GaN, amorphous GaN, gallium amide, gallium imide, and mixtures thereof. The nutrient material may further comprise a mineralizer, for example, a basic mineralizer, such as, for example, LiNH₂, NaNH₂, or KNH₂; metallic Li, Na, or K; other minerals such as ionic salts of Li⁺, Na⁺, K⁺, Ca²⁺, or Mg²⁺; or a mineralizer such as NH₄F, NH₄Cl, NH₄Br, or NH₄I.

In various embodiments, the source dissolution region may be configured to be externally heated at a first temperature. The first temperature may be any temperature suitable for dissolving the group III nutrient material. In specific embodiments, the first temperature may range from 500° C. to 600° C., or in other embodiments from about 500° C. to about 560° C. Given the adverse environment within the source dissolution region (i.e., high temperature and pressure), measurement of the temperature of the source dissolution region is typically done by measuring the external temperature of the reactor at the source dissolution region.

According to various embodiments, the reactors may also comprise a crystal growth region. The crystal growth region may be configured to provide a place for growth of the group III nitride crystals. For example, in certain embodiments, the crystal growth region may be configured to contain at least one group III nitride deposition substrate. The deposition substrate may be a material onto which the group III nitride crystals may deposit or crystallize from the supercritical ammonia solution. Typical deposition substrates will have a surface contour or structure that provides the correct surface for optimal crystal deposition. In one embodiment, the deposition substrate may be a seed crystal of the group III nitride. For example, in those reactors designed for growing GaN crystals, the seed crystal may be a single crystalline GaN seed crystal.

In various embodiments, the crystal growth region may be configured to be externally heated at a second temperature. The second temperature may be any temperature suitable for growth of the group III crystals. In specific embodiments, the second temperature may range from 500° C. to 600° C., or in other embodiments from about 550° C. to about 600° C. Given the adverse environment within the crystal growth region (i.e., high temperature and pressure), measurement of the temperature in the crystal growth region is typically done by measuring the external temperature of the reactor at the crystal growth region.

Although certain embodiments of the reactors are described as comprising two externally heated zones, each heating zone can be divided into two or more further externally heated zones in order to attain a favorable temperature profile.

As described herein, group III nitrides such as GaN, may display retrograde solubility in supercritical ammonobasic solutions. Thus, according to certain embodiments, the reactors may be configured such that the second temperature may be greater than the first temperature. Therefore, certain embodiments of the reactors may be configured such that the temperature of the crystal growth region (as measured by the external temperature of the crystal growth region) may be greater than the external temperature of the source dissolution region (as measured by the external temperature of the source dissolution region). In other embodiments, the temperatures of the source dissolution region and the crystal growth region may be substantially equal. In still other embodiments, improved crystal quality may be observed when the reactors are configured such that the temperature of the crystal growth region (as measured by the external temperature of the crystal growth region, i.e., the second temperature) may be less than the external temperature of the source dissolution region (as measured by the external temperature of the source dissolution region, i.e., the first temperature). According to certain embodiments where the reactors are configured so the first temperature is greater than the second temperature, the total amount of group III nitride deposited on the wall of the reactor (and structures within the reactor other than the seed crystal) is suppressed. In specific embodiments, the amount of group III nitride deposited on the wall of the reactor may be less than 20% of the total consumption of the group III nutrient material.

According to the various embodiments, the source dissolution region is configured such that the group III nutrient material dissolves in the supercritical ammonia (optionally with the mineralizer) to form a solution comprising the group III nitride and supercritical ammonia. The group III nitride in the supercritical ammonia then flows through the reactor to the crystal growth region where it deposits and grows as crystalline group III nitride, for example on the seed crystal. The concentration and/or temperature gradient formed by the dissolution of the nutrient material and the crystal growth of the group III nitride results in a flow of the dissolved group III nitride from the source dissolution region to the crystal growth region. The various embodiments of the reactors of the present disclosure provide for group III nitride crystals having a quality suitable for use in various electronic applications at acceptable growth rates. For example, the reactors allow for the growth of group III nitride crystals (such as, for example, GaN) having full width half maximum value of X-ray rocking curve from 002 reflection less than 200 arcsec at a growth rate of 100 μm/day or higher.

According to various embodiments, the reactors of the present disclosure may comprise a intermediate region between the source dissolution region and the crystal growth region. While not intending to be limited by any theory, it is believed that intermediate region provides for improved crystal growth by acting to provide a solution of group III nitride and supercritical ammonia that has at least one of a more uniform temperature or a more uniform concentration compared to solutions in similar prior art reactors having a different intermediate region configuration or no intermediate region. In certain embodiments, the intermediate region of the present reactors may be configured to provide at least one of improved static mixing or improved thermal uniformity.

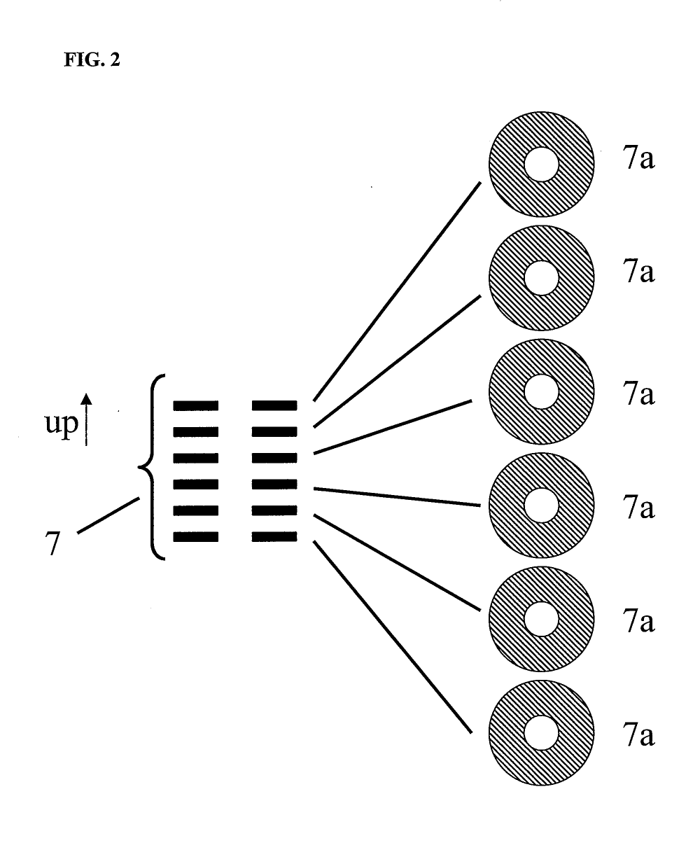

In one embodiment, the reactor of the present disclosure may comprise an intermediate region configured as a static mixing region. According to these embodiments, the static mixing region may be configured to equilibrate or homogenize the solution of the group III nitride in supercritical ammonia by a static mixing process. As used herein, the terms “equilibrate” and “homogenize” include where the solution shows improved equilibration or homogeneity, for example of concentration or temperature, or both, in the static mixing region or the crystal growth region, or both. The resulting equilibrated solution may have at least one of a more uniform temperature and a more uniform concentration compared to a solution in an otherwise identical reactor differing only in having an intermediate region as described in the prior art, for example, differing only in that it has an intermediate region in place of the static mixing region and comprising a plurality of plates, wherein each plate has an identical single opening of the same size aligned along a longitudinal axis of the reactor. FIG. 2 illustrates a prior art intermediate region 7 comprising a plurality of identical plates 7a having a single opening of the same size and location which are aligned along a longitudinal axis when the plates are oriented in a parallel fashion. The alignment of the openings on the plates result in a linear flow-path for the solution thorough the plurality of plates of the intermediate region.

According to the embodiments of the reactors of the present disclosure, the static mixing region may be configured to mix the solution by at least one of turbulent mixing and convective mixing. The turbulent mixing may result from eddies within the concentration gradient of the solution as the solution passes through the static mixing region, for example, as the solution flows along a non-linear flow path. Convective mixing may result from temperature convections within the solution resulting from temperature differentials within the solution.

According to certain embodiments of the reactors, the static mixing region may comprise a plurality of plates oriented transverse to the longitudinal axis of the reactor. The plurality of plates may comprise a first plate having one or more openings and a second plate having one or more openings that are different from the one or more openings in the first plate, wherein the openings are sized and/or positioned on the plate to produce the mixing of the solution. The plurality of plates may comprise additional plates that may be similar to either the first plate or the second plate. The openings on the second plate may be different from the openings on the first plate by having a different location on the second plate compared to the first plate (i.e., offset from the location on the first plate when the plates are oriented in a parallel fashion). Alternatively, the opening on the second plate may differ by having a larger or smaller perimeter compared to the opening on the first plate. Alternatively, the opening on the second plate may have a different shape than the opening on the first plate (e.g., square versus circular). Alternatively, there may be more openings on the second plate that one the first plate. In certain embodiments, the openings of the different plates may differ by two or more of these factors. When the plurality of plates are oriented transverse to the longitudinal axis of the reactor, the openings will define a flow-path for the solution from the source dissolution region to the crystal growth region that is non-linear, thereby creating a static mixing phenomena within the solution.

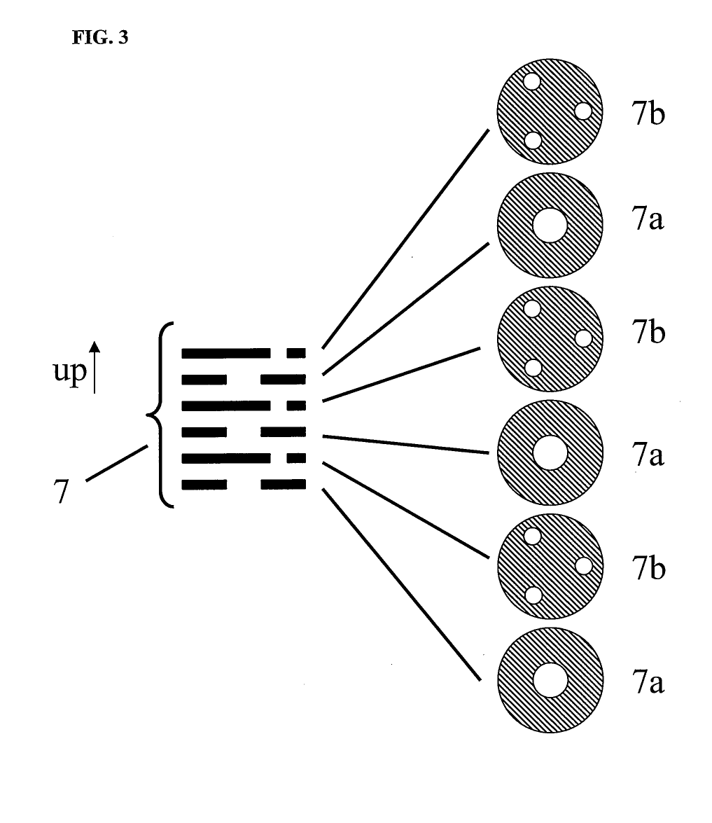

According to one embodiment, at least one of the one or more openings on the first plate may be offset from the one or more openings on the second plate such that there is no linear flow-path for the solution through the plurality of plates. FIG. 3 illustrates one example of this embodiment. The plurality of plates 7 are oriented transverse to the flow of the solution with a first plate 7a having a single opening centered in the plate and a second plate 7b having three openings, each of which are offset from the opening on the first plate 7a. As shown in FIG. 3, the plates may be oriented parallel to each other, such that the openings on adjacent plates are offset and define a non-linear flow-path through the plates. One skilled in the art will understand that alternative arrangements of the plates are possible that still result in a non-linear flow-path and are within the scope of this embodiment.

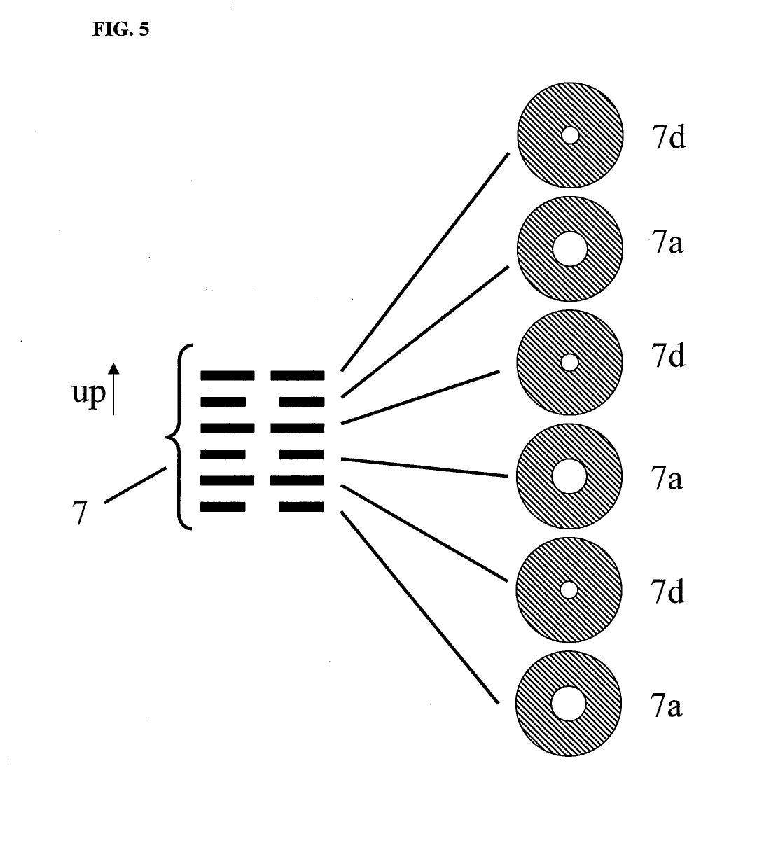

According to another embodiment, the plurality of plates may be configured such that at least one of the one or more openings on the first plate has a larger perimeter than the one or more openings on the second plate. In certain embodiments, the second plate may comprise an opening that is longitudinally aligned with the larger perimeter opening on the first plate. While not being limited by any theory, static mixing may result from local differences in concentration flow between the larger and smaller perimeter openings, such as by a bottleneck created at the smaller perimeter openings. FIG. 5 illustrates one example of this embodiment. The plurality of plates 7 are oriented transverse to the flow of the solution with a first plate 7a having a large perimeter single opening centered in the plate and a second plate 7d having small perimeter opening relative to the opening on the first plate 7a. As shown in FIG. 5, the plates may be oriented parallel to each other to define a flow-path having bottlenecks at each plate having a smaller perimeter opening, thereby creating static mixing.

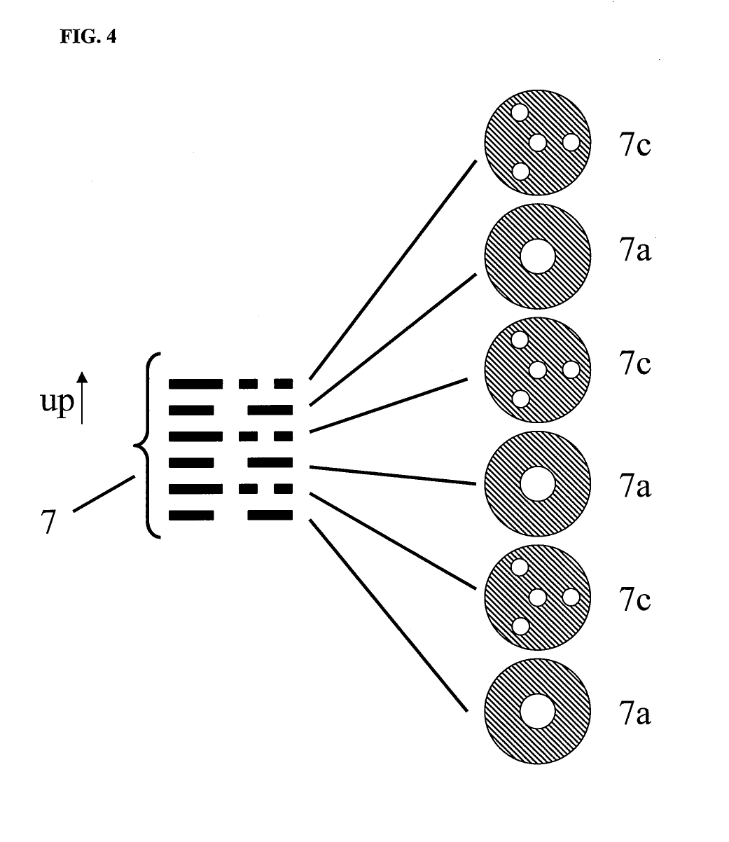

According to another embodiment, the plurality of plates may be configured such that the second plate may comprise at least a second opening that is offset from the larger perimeter opening on the first plate. In this embodiment, static mixing may result from local differences in concentration flow between the larger and smaller perimeter openings, such as by a bottleneck created by the smaller perimeter openings and also by the non-linear flow-path created by the offset openings. FIG. 4 illustrates one example of this embodiment. The plurality of plates 7 are oriented transverse to the flow of the solution with a first plate 7a having a large perimeter single opening centered in the plate and a second plate 7c having four small perimeter opening, three of which are offset relative to the opening on the first plate 7a. As shown in FIG. 5, the plates may be oriented parallel to each other to define a flow-path having bottlenecks at each plate having a smaller perimeter openings and also a non-linear flow-path through the offset openings, thereby creating static mixing.

The plurality of plates may be oriented transverse to the flow of the solution and held in position by a variety of structural features. For example, in certain embodiments, the plates may have one more legs protruding from a face of the plate, such that the plates may be stacked one atop another in a roughly parallel orientation. In other embodiments, the plates may be held in position by being fastened to a structure, such as, to the wall of the reactor at one or more positions on the plate perimeter or to a scaffold structure designed to hold the plates in a roughly parallel orientation, transverse to the flow. Various structural mechanisms and designs for maintaining the plates in the parallel fashion are within the skill of the artisan in view of this disclosure.

In other embodiments, the static mixing region may comprise an insert. The insert may be designed to have at least one flow path configured to induce static mixing of the solution. In one embodiment, the flow-path may be a non-linear or circuitous flow path. For example, certain embodiments of the insert may comprise a plurality of flow impediments configured to induce the static mixing of the solution. Flow impediments may include structural features, such as plates, cylinders, cones, columns and other geometric structures, placed within the flow path of the solution to divert and statically mix the flow as it travels through the insert. In certain embodiments, the insert may comprise a plurality of plates oriented transverse to the longitudinal axis of the reactor. The plurality of plates may comprise a first plate having one or more openings and a second plate having one or more openings different from the one or more openings of the first plate, wherein the openings are configured to produce static mixing of the solution. Examples of opening configurations on the first plate and the second plate are described in detail herein. The plurality of plates may further comprise a third or more plates as described herein.

Other suitable static mixer inserts and configurations may include inserts configured similar to low pressure drop static mixers (available from Charles Ross and Sons Co., Hauppauge, N.Y.) or ultra mixer technology (available from Komax Systems Inc., Huntington Beach, Calif.) which are typically utilized in in-line mixing in pipeline and other dynamic flow applications. Inserts such as these may provide at least one flow path resulting in static mixing of the flow of group III nitride dissolved in the supercritical ammonia as it flows from the source dissolution region to the crystal growth region.

According to those embodiments of the static mixing region comprising a plurality of plates, each plate in the plurality of plates may be separated from an adjacent plate by at least 1 mm. In specific embodiments, the separation distance between the plates may range from 1 mm to 20 mm, or even from 1 mm to 10 mm. One skilled in the art will recognize that the separation distances between the plates may vary based on the overall size or volume of the reactor, as described herein. Plate separation distances should be sufficient to ensure effective static mixing of the group III nitride solution within the static mixing region.

As discussed herein, the source dissolution region may be configured to be externally heated at a first temperature and the crystal growth region may be configured to be heated at a second temperature. Under standard ammonothermal conditions, the second temperature may be greater than the first temperature. However, the inventors have discovered that in certain reactor designs, the external temperature for the crystal growth region need not necessarily higher than the external temperature of the nutrient region even under the basic ammonothermal growth conditions. Under specific conditions, high quality GaN crystals with satisfactory growth rates can be grown by setting higher external temperature for the source dissolution region (first temperature) than for the external temperature of the crystal growth region (second temperature) with the reactor designs and baffle regions of the present disclosure. In addition, in certain embodiments where the external temperature of the source dissolution region (first temperature) is greater than the external temperature of the crystal growth region (second temperature), the inventors have observed that the amount of group III nitride deposited on the walls of the reactor may be reduced or suppressed, for example, to an amount less than 20% of the total consumption of group III nutrient material (i.e., the amount of group III nutrient that is dissolved from the source dissolution region). Thus, according to these embodiments, the efficiency of crystal growth may be improved and/or waste of nutrient material may be reduced.

According to certain embodiments, the static mixing region of specific reactor designs may be configured to equilibrate a temperature of the solution as it passes through the static mixing region. In specific embodiments, the static mixing provided by the static mixing region may be such that the temperature of the solution at an interface of the static mixing region and the crystal growth region is substantially equal to the temperature of the crystal growth region. As used herein, the term “substantially equal”, when used in reference to temperatures, means within ±2% of the referenced temperature. While not intending to be limited by any theory, it is believed that under the reactor conditions, if the group III nitride and supercritical ammonia solution enters the crystal growth region having a temperature that is substantially equal to the temperature of the crystal growth region, improved crystal growth may occur.

Other embodiments of the reactors of the present disclosure may be configured such that the region intermediate the source dissolution region and the crystal growth region may comprise an intermediate heating region. For example, according to these embodiments, the reactor for growing group III nitride crystals may comprise a high pressure ammonothermal reactor vessel, as described herein; a source dissolution region configured to be externally heated at a first temperature and contain a group III nutrient materials, as described herein; a crystal growth region configured to be externally heated at a second temperature and contain at least one group III nitride deposition substrate, as described herein; and the intermediate heating region. According to these embodiments, the intermediate heating region may comprise at least one flow channels through which the fluid or solution comprising the group III nitride and the supercritical ammonia may flow. The flow channels may be configured to have a path-length for the fluid flowing through the heating region, wherein the path-length is greater than a path-length of a flow channel parallel to a longitudinal axis of the reactor from the source dissolution region to the crystal growth region. In various embodiment, the flow-path may be a non-linear flow-path.

According to various embodiments, the at least one flow channel may be configured so that the fluid at the interface of the intermediate heating region and the crystal growth region has a temperature that is substantially equal to the temperature of the crystal growth region. As described herein, in various embodiments, the first temperature may be greater than the second temperature and in other embodiments, the second temperature may be greater than the first temperature.

In certain embodiments, the intermediate heating region may comprise an insert defining the at least one flow channel. Examples of suitable inserts are described herein. According to specific embodiments, the intermediate heating region ay comprise a plurality of plates oriented transverse to a longitudinal axis of the reactor. The plurality of plates may comprise a first plate having one or more openings and a second plate having one or more openings that are different from the one or more openings of the first plate, wherein the openings of the plates define the at least one flow channel. The plurality of plates may further comprise additional plates. Examples of various plate opening configurations and structural features for the first and second (and additional) plates are described herein. As described herein, the plates may be separated from adjacent plates by at least 1 mm.

According to specific embodiments, the reactor for growing group III nitride crystals may comprise a high pressure ammonothermal reactor vessel, as described herein; a source dissolution region configured to contain a group III nutrient, as described herein; a crystal growth region configured to contain at least one group III nitride seed crystal, as described herein; and a baffle region between the source dissolution region and the crystal growth region. According to these embodiments, the baffle region may comprise a plurality of baffle plates oriented transverse to a flow comprising a group III nitride and supercritical ammonia from the source dissolution region to the crystal growth region. The plurality of plates may comprise a first plate having one or more openings and a second plate having one or more openings that is different from the one or more openings of the first plate. The plurality of plates may further comprise additional baffle plates.

Examples of the possible orientations and configurations of the one or more openings on the first and second plates are described in detail herein and illustrated in the Figures. For example, according to one embodiment, the one or more openings on the first plate are offset from the one or more openings on the second plate. According to other embodiments, the one or more openings on the first plate may be offset from the one or more openings on the second plate such that there is no linear flow path through the baffle region. In still other embodiments, at least one of the one or more openings on the first plate may have a larger perimeter than the one or more openings on the second plate. In specific embodiments, the second plate may comprise an opening that is longitudinally aligned with the larger perimeter opening on the first plate. Alternatively, or in addition, the second plate may comprise at least a second opening offset from the larger perimeter opening on the first plate.

Although the various embodiments of the reactor designs described herein have been described having a static mixing region, an intermediate temperature region, and a baffle region, it should be understood that these structures describe various embodiments of the intermediate region that acts to produce a more uniform fluid (concentration and/or temperature) and result in a controlled crystal growth process of the group III nitrides within the crystal growth region. According to the various embodiments, the reactors are designed such that the solution in the crystal growth region has a more uniform temperature and/or concentration compared to an otherwise identical reactor differing only in having an intermediate region comprising a plurality of plates, wherein each plate has a singe opening of the same size aligned along a longitudinal axis of the reactor.

The ammonothermal process involves high temperatures and pressures under extreme and corrosive conditions that require the reactor to be made from an inert material. According to the various embodiments of the reactors described herein, the various reactor components, such as, for example, the static mixing region, an intermediate region, the plurality of plates, an insert, a flow impediment, may comprise an inert material such as a nickel containing alloy. Suitable nickel alloys include precipitation hardened Ni—Cr based superalloys, such as Rene 41, Inconel X-750, and Inconel 718 or other suitable nickel based superalloys.

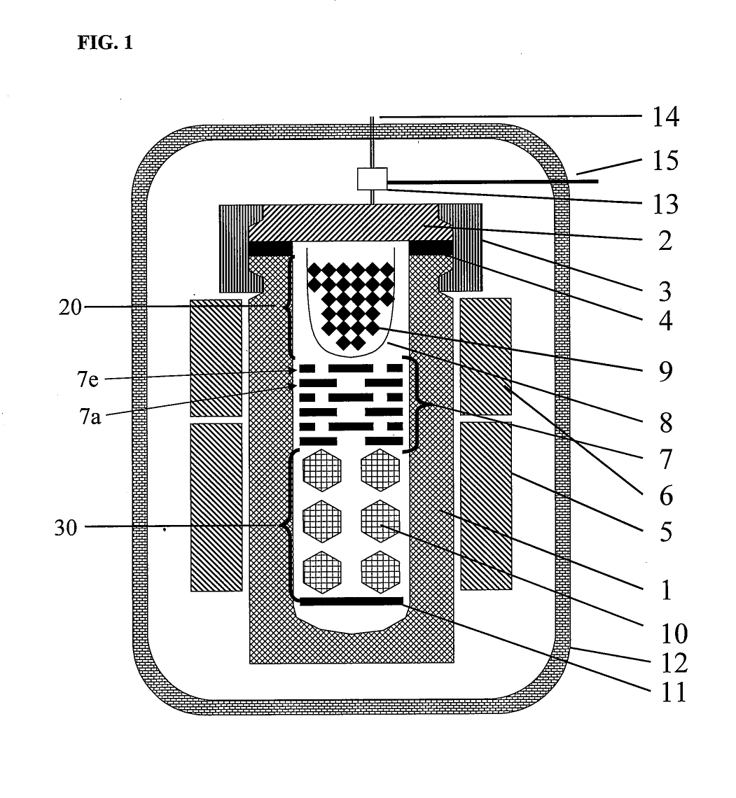

Referring now to FIG. 1, an exemplary embodiment of one reactor according to the present disclosure is set forth. FIG. 1 illustrates the high pressure ammonothermal reactor vessel 1, configured to have a lid 2, sealed by gasket 4 and held in place by clamp 3. External heater(s) 6 surrounds source dissolution region 20 and external heater(s) 5 surrounds the crystal growth region 30. The source dissolution region 20 includes nutrient basket 8 configured to contain the group III nutrient material 9. The crystal growth region 30 includes group III nitride seed crystals 10 and a bottom plate 11 at the bottom of the reactor. In between the source dissolution region and the crystal growth region is the intermediate region 7, comprising a plurality of plates including a first plate 7a having one or more openings and a second plate 7e having one or more openings different than the one or more openings of first plate 7a. Plates 7a and 7e define a non-linear flow path through intermediate region 7. Ammonia and other liquid or gas may added or removed from the reactor by conduit 14 through valve 13, which is operated by device 15. For safety purposes, reactor vessel 1 is surrounded by a blast containment enclosure 12. Although the various Figures illustrate one exemplary reactor designs having six baffle plates, other numbers of baffle plates can be utilized to provide improved crystal growth.

The present disclosure also provides for various methods of growing high quality group III nitride crystals, such as, for example, GaN crystals, suitable for use in various opto-electronic and electronic devices. According to certain embodiments, the methods may comprise the steps of passing a solution comprising a group III nitride and supercritical ammonia through an intermediate region, such as a static mixing region, an intermediate heating region, or a baffle region, as described herein, and growing a group III nitride crystal in a crystal growth region. The group III nitride crystal may be grown on a group III nitride crystal deposition substrate, such as, for example, a group III nitride seed crystal. In certain embodiments, the solution may be passed through a baffle region comprising a plurality of flow impediments, such as the flow impediments described herein, wherein the flow impediments define a flow path for the solution and the path-length of the flow path is greater than a path-length of a flow path parallel to a longitudinal axis of the baffle region. In one series of embodiments, the plurality of flow impediments may comprise a plurality of baffle plates oriented transverse to a longitudinal axis of the baffle region. The plurality of plates may comprise a first plate having one or more openings and a second plate having one or more openings different than the one or more openings of the first plate.

Various examples of plate and opening configurations for the plurality of plates are described in detail herein. For example, according to one embodiment, the one or more openings on the first plate are offset from the one or more openings on the second plate. According to other embodiments, the one or more openings on the first plate may be offset from the one or more openings on the second plate such that there is no linear flow path through the baffle region. In still other embodiments, at least one of the one or more openings on the first plate may have a larger perimeter than the one or more openings on the second plate. In specific embodiments, the second plate may comprise an opening that is longitudinally aligned with a larger perimeter opening on the first plate. Alternatively, or in addition, the second plate may comprise at least a second opening offset from a larger perimeter opening on the first plate.

The methods of the current disclosure allow for the growth of high quality group III nitride crystals at faster rates than typically seen in the prior art. Suitable high quality crystals may have a full width half maximum value of X-ray rocking curve from 002 reflection of less than 200 arcsec. For example, certain embodiments of the methods may provide for growth of group III nitride crystals at growth rates of at least 100 μm/day. Specific embodiments of the methods may be directed to growing crystals of GaN, wherein the crystals have a full width half maximum value of X-ray rocking curve from 002 reflection of less than 200 arcsec and are grown at a growth rate of at least 100 μm/day.

According to other embodiments, the methods may further comprise dissolving a group III nutrient material in the supercritical ammonia. Suitable group III nutrients are described in detail elsewhere herein. In certain embodiments, the solution may further comprise a mineralizer. For example, the solution may further comprise one or more ions selected from the group consisting of Li⁺, Na⁺, K⁺, Ca²⁺, Mg²⁺, and mixtures of any thereof. Other embodiments of the methods may comprise externally heating the source dissolution region to a first temperature and externally heating the crystal growth region to a second temperature, wherein the first temperature is greater than the second temperature.

According to specific embodiments, the disclosed reactors and methods enable growth of higher quality GaN crystals while maintaining growth rates higher than 100 μm/day. While not limited to any theory, the improved crystal growth may be due to the intermediate region providing better thermal isolation between the source dissolution region and the crystal growth region without decreasing the conductance. Typically, the crystal quality and the growth rate are in a trade-off relationship. However, the new reactor design enables one to achieve both high crystal quality and high growth rate and, therefore, improves the productivity of GaN wafers by the ammonothermal growth process.

The foregoing description of the various embodiments has been presented for the purposes of illustration and description. It is not intended to be exhaustive or to limit the invention to the precise form disclosed. Many modifications and variations are possible in light of the teachings herein. It is intended that the scope of the invention be limited not by this detailed description, but rather by the claims appended hereto.

The various embodiments of the present disclosure will be better understood when read in conjunction with the following non-limiting Examples. The procedures set forth in the Examples below are not intended to be limiting herein, as those skilled in the art will appreciate that various modifications to the procedures set forth in the Examples, as well as to other procedures not described in the Examples, may be useful in practicing the invention as described herein and set forth in the appended claims. In the following examples, conventional reactors and reactors according to the present disclosure are compared in terms of crystal quality and growth rate.

### Examples

### Example 1

### GaN Growth With Conventional Reactor Design

In this example, a high-pressure vessel having an inner diameter of 1 inch was used to grow GaN in supercritical ammonobasic solution using a conventional reactor design. All necessary sources and internal components including 10 g of polycrystalline GaN nutrient held in a Ni basket, 0.429 mm-thick single crystalline GaN seeds, and a baffle region having six baffle plates with each separation of 10 mm as shown in FIG. 2 were loaded into a glove box together with the high-pressure vessel. The glove box is filled with nitrogen and the oxygen and moisture concentration is maintained to be less than 1 ppm. Since the mineralizers are reactive with oxygen and moisture, the mineralizers are stored in the glove box at all times. 2.4 g of Na was used as a mineralizer. After loading the mineralizer into the high-pressure vessel, six baffles together with a seed and nutrient were loaded. After sealing the high-pressure vessel, it was taken out of the glove box. The high-pressure vessel was connected to a gas/vacuum system, which can pump down the vessel as well as supply NH₃ to the vessel. The high-pressure vessel was evacuated with a turbo molecular pump to achieve pressure less than 1×10⁻⁵ mbar. The actual pressure before filling ammonia was 1.7×10⁻⁶ mbar. In this way, residual oxygen and moisture on the inner wall of the high-pressure vessel were removed. After this, the high-pressure vessel was chilled with liquid nitrogen and NH₃ was condensed in the high-pressure vessel. Approximately 40 g of NH₃ was charged in the high-pressure vessel. After closing the high-pressure valve of the high-pressure vessel, it was transferred to a two-zone furnace. The high-pressure vessel was heated up. First, only the furnace for the nutrient region was elevated to 550° C. while the furnace for the crystallization region was off. This reverse temperature setting was discovered to be beneficial for improving crystal quality as shown in the related patent (U.S. provisional application 61/058,910). After 24 hours, the temperatures for the crystallization region and the nutrient region were set to 595° C. and 510° C., respectively. After 4 days, ammonia was released and the high-pressure vessel was opened. The thickness of the crystal became 1.04 mm and the resulting growth rate was 153 μm/day. The full width half maximum value of the x-ray diffraction from (002) planes were 4741 arcsec for Ga-face and 267 arcsec for N-face, respectively.

### Example 2

### GaN Growth With Reactor Design of FIG. 3

In this example, a high-pressure vessel having an inner diameter of 1 inch was used to grow higher quality GaN in supercritical ammonobasic solution. All necessary sources and internal components including 5 g of polycrystalline GaN nutrient held in a Ni basket, 0.458 mm-thick single crystalline GaN seeds, and a baffle region having six baffle plates with each separation of 10 mm as shown in FIG. 3 were loaded into a glove box together with the high-pressure vessel. The glove box is filled with nitrogen and the oxygen and moisture concentration is maintained to be less than 1 ppm. Since the mineralizers are reactive with oxygen and moisture, the mineralizers are stored in the glove box at all times. 2.4 g of Na was used as a mineralizer. After loading the mineralizer into the high-pressure vessel, six baffles together with a seed and nutrient were loaded. After sealing the high-pressure vessel, it was taken out of the glove box. The high-pressure vessel was connected to a gas/vacuum system, which can pump down the vessel as well as supply NH₃ to the vessel. The high-pressure vessel was evacuated with a turbo molecular pump to achieve pressure less than 1×10⁻⁵ mbar. The actual pressure before filling ammonia was 1.6×10⁻⁶ mbar. In this way, residual oxygen and moisture on the inner wall of the high-pressure vessel were removed. After this, the high-pressure vessel was chilled with liquid nitrogen and NH₃ was condensed in the high-pressure vessel. Approximately 40.6 g of NH₃ was charged in the high-pressure vessel. After closing the high-pressure valve of the high-pressure vessel, it was transferred to a two-zone furnace. The high-pressure vessel was heated up. First, only the furnace for the nutrient region was elevated to 550° C. while the furnace for the crystallization region was off. This reverse temperature setting was discovered to be beneficial for improving crystal quality as shown in the related patent (U.S. provisional application 61/058,910). After 24 hours, the temperatures for the crystallization region and the nutrient region were set to 595° C. and 510° C. respectively. After 4 days, ammonia was released and the high-pressure vessel was opened. The thickness of the crystal became 0.934 mm and the resulting growth rate was 119 μm/day. The full width half maximum value of the x-ray diffraction from (002) planes were 1531 arcsec for Ga-face and 73 arcsec for N-face. Compared to the crystal in the Example 1, the crystal grown with the baffle region of the present disclosure showed improved crystal quality (i.e. smaller full width half maximum number). At the same time, the growth rate was maintained higher than 100 μm/day.

### Example 3

### GaN Growth With Reactor Design FIG. 4

In this example, a high-pressure vessel having an inner diameter of 1 inch was used to grow better quality GaN in supercritical ammonobasic solution. All necessary sources and internal components including 5 g of polycrystalline GaN nutrient held in a Ni basket, 0.462 mm-thick single crystalline GaN seeds, and a baffle region having six baffle plates with each separation of 10 mm as shown in FIG. 4 were loaded into a glove box together with the high-pressure vessel. The glove box is filled with nitrogen and the oxygen and moisture concentration is maintained to be less than 1 ppm. Since the mineralizers are reactive with oxygen and moisture, the mineralizers are stored in the glove box at all times. 2.4 g of Na was used as a mineralizer. After loading the mineralizer into the high-pressure vessel, six baffles together with a seed and nutrient were loaded. After sealing the high-pressure vessel, it was taken out of the glove box. The high-pressure vessel was connected to a gas/vacuum system, which can pump down the vessel as well as supply NH₃ to the vessel. The high-pressure vessel was evacuated with a turbo molecular pump to achieve pressure less than 1×10⁻⁵ mbar. The actual pressure before filling ammonia was 1.7×10⁻⁶ mbar. In this way, residual oxygen and moisture on the inner wall of the high-pressure vessel were removed. After this, the high-pressure vessel was chilled with liquid nitrogen and NH₃ was condensed in the high-pressure vessel. Approximately 40.3 g of NH₃ was charged in the high-pressure vessel. After closing the high-pressure valve of the high-pressure vessel, it was transferred to a two-zone furnace. The high-pressure vessel was heated up. First, only the furnace for the nutrient region was elevated to 550° C. while the furnace for the crystallization region was off. This reverse temperature setting was discovered to be beneficial for improving crystal quality as shown in the related patent (U.S. provisional application 61/058,910). After 24 hours, the temperatures for the crystallization region and the nutrient region were set to 595° C. and 510° C. respectively. After 4 days, ammonia was released and the high-pressure vessel was opened. The thickness of the crystal became 0.919 μm and the resulting growth rate was 114 μm/day. The full width half maximum value of the x-ray diffraction from (002) planes were 1338 arcsec for Ga-face and 100 arcsec for N-face. Compared to the crystal in the Example 1, the crystal grown with the baffle region of the present disclosure showed improved crystal quality (i.e. smaller full width half maximum number). At the same time, the growth rate was maintained higher than 100 μm/day.

### Example 4

### GaN Growth With Reactor Design of FIG. 3, Higher Temperature for Nutrient Region

In this example, a high-pressure vessel having an inner diameter of 1 inch was used to grow better quality GaN in supercritical ammonobasic solution. All necessary sources and internal components including 5 g of polycrystalline GaN nutrient held in a Ni basket, 0.394 mm-thick single crystalline GaN seeds, and a baffle region having six baffle plates with each separation of 10 mm as shown in FIG. 3 were loaded into a glove box together with the high-pressure vessel. The glove box is filled with nitrogen and the oxygen and moisture concentration is maintained to be less than 1 ppm. Since the mineralizers are reactive with oxygen and moisture, the mineralizers are stored in the glove box at all times. 2.4 g of Na was used as a mineralizer. After loading the mineralizer into the high-pressure vessel, six baffles together with a seed and nutrient were loaded. After sealing the high-pressure vessel, the vessel was taken out of the glove box. The high-pressure vessel was connected to a gas/vacuum system, which can pump down the vessel as well as supply NH₃ to the vessel. The high-pressure vessel was evacuated with a turbo molecular pump to achieve pressure less than 1×10⁻⁵ mbar. The actual pressure before filling ammonia was 1.6×10⁻⁶ mbar. In this way, residual oxygen and moisture on the inner wall of the high-pressure vessel were removed. After this, the high-pressure vessel was chilled with liquid nitrogen and NH₃ was condensed in the high-pressure vessel. Approximately 40.4 g of NH₃ was charged in the high-pressure vessel. After closing the high-pressure valve of the high-pressure vessel, the vessel was transferred to a two-zone furnace. The high-pressure vessel was heated up. First, only the furnace for the nutrient region was elevated to 550° C. while the furnace for the crystallization region was off. This reverse temperature setting was discovered to be beneficial for improving crystal quality as shown in the related patent (U.S. provisional application 61/058,910). After 24 hours, the temperatures for the crystallization region and the nutrient region were set to 575° C. and 585° C. respectively. After 7 days, ammonia was released and the high-pressure vessel was opened. The thickness of the crystal was 0.999 mm and the resulting growth rate was 86 μm/day. The full width half maximum value of the x-ray diffraction from (002) planes were 191 arcsec for Ga-face and 170 arcsec for N-face. Compared to the crystal in the Example 1, the crystal grown with the baffle region of the present disclosure showed improved crystal quality (i.e. smaller full width half maximum number). At the same time, the growth rate was maintained at acceptable speed. The consumption of polycrystalline GaN was 1.1 g and total weight of GaN deposited on the wall was approximately 0.2 g, which was less than 20% of the total consumption of the nutrient. This baffle design with reverse-temperature setting is effective to achieve high efficient growth.

Although examples herein describe a process step in which NH₃ is released at elevated temperature, NH₃ can also be released after the high-pressure vessel is cooled as long as seizing of screws does not occur.

We claim:

1. A reactor for growing group III nitride crystals, comprising:
a high pressure ammonothermal reactor vessel;
a source dissolution region configured to contain a group III nutrient material;
a crystal growth region configured to contain at least one group III nitride seed crystal; and
a static mixing region between the source dissolution region and the crystal growth region, wherein the static mixing region is configured to equilibrate a solution comprising a group III nitride and supercritical ammonia, wherein the equilibrated solution has at least one of a more uniform concentration and a more uniform temperature compared to a solution in an otherwise identical reactor differing only in having an intermediate region in place of the static mixing region and comprising a plurality of plates, wherein each plate has a single opening of same size aligned along a longitudinal axis of the reactor.

2. The reactor of claim 1, wherein the static mixing region is configured to mix the solution by at least one of turbulent mixing and convective mixing.

3. The reactor of claim 1, wherein the static mixing region comprises a plurality of plates oriented transverse to a longitudinal axis of the reactor,
the plurality of plates comprising a first plate having one or more openings and a second plate having one or more openings different from the one or more openings of the first plate, wherein the openings are sized and/or positioned to produce mixing of the solution.

4. The reactor of claim 3, wherein at least one of the one or more openings on the first plate are offset from the one or more openings on the second plate such that there is no linear flow-path for the solution through the plurality of plates.

5. The reactor of claim 3, wherein at least one of the one or more openings on the first plate has a larger perimeter than the one or more opening on the second plate.

6. The reactor of claim 5, wherein the second plate comprises an opening that is longitudinally aligned with the larger perimeter opening on the first plate.

7. The reactor of claim 6, wherein the second plate comprises at least a second opening offset from the large perimeter opening on the first plate.

8. The reactor of claim 1, wherein the static mixing region comprises an insert having at least one flow path configured to induce static mixing of the solution.

9. The reactor of claim 8, wherein the flow path is a circuitous flow path.

10. The reactor of claim 8, wherein the insert comprises a plurality of flow impediments configured to induce the static mixing of the solution.

11. The reactor of claim 8, wherein the insert comprises a plurality of plates oriented transverse to a longitudinal axis of the reactor,
the plurality of plates comprising a first plate having one or more openings and a second plate having one or more openings different from the one or more openings of the first plate, wherein the openings are configured to produce static mixing of the solution.

12. The reactor of claim 3, wherein each plate is separated from an adjacent plate by at least 1 mm.

13. The reactor of claim 1, wherein the source dissolution region is configured to be externally heated at a first temperature and the crystal growth region is configured to be externally heated at a second temperature.

14. The reactor of claim 13, wherein the static mixing region is further configured to equilibrate a temperature of the solution such that the temperature of the solution at an interface of the static mixing region is substantially equal to the temperature of the crystal growth region.

15. The reactor of claim 13, wherein the first temperature is greater than the second temperature.

16. The reactor of claim 15, wherein a total amount of group III nitride deposited on a wall of the reactor is suppressed to be less than 20% of a total consumption of the group III nutrient.

17. The reactor of claim 13, wherein the first temperature ranges from 500° C. to 600° C. and the second temperature ranges from 500° C. and 600° C.

18. The reactor of claim 1, wherein the group III nitride crystals are GaN crystals.

19. The reactor of claim 1, wherein the static mixing region comprises a nickel alloy.

20. A reactor for growing group III nitride crystals, comprising:
a high pressure ammonothermal reactor vessel;
a source dissolution region configured to be externally heated at a first temperature and contain a group III nutrient material;
a crystal growth region configured to be externally heated at a second temperature and contain at least one group III nitride seed crystal; and
an intermediate heating region having at least one flow channel, the flow channel having a path-length for a fluid flowing through the intermediate heating region that is greater than a path-length of a flow channel parallel to a longitudinal axis from the source dissolution region to the crystal growth region.

21. The reactor of claim 20, wherein the first temperature is greater than the second temperature.

22. The reactor of claim 21, wherein a total amount of group III nitride deposited on a wall of the reactor is suppressed to be less than 20% of a total consumption of the group III nutrient.

23. The reactor of claim 20, wherein the at least one flow channel is configured so the fluid at an interface of the intermediate heating region and the crystal growth region has a temperature substantially equal to the temperature of the crystal growth region.

24. The reactor of claim 20, wherein the intermediate heating region comprises an insert defining the at least one flow channel.

25. The reactor of claim 20, wherein the intermediate heating region comprises a plurality of plates oriented transverse to a longitudinal axis of the reactor,
the plurality of plates comprising a first plate having one or more openings and a second plate having one or more openings different from the one or more openings of the first plate, wherein the openings define the at least one flow channel.

26. The reactor of claim 25, wherein each plate is separated from an adjacent plate by at least 1 mm.

27. The reactor of claim 20, wherein the first temperature ranges from 500° C. to 600° C. and the second temperature ranges from 500° C. and 600° C.

28. The reactor of claim 20, wherein the group III nitride seed crystals are GaN crystals.

29. The reactor of claim 20, wherein the intermediate heating region comprises a nickel alloy.

30. A method for growing group III nitride crystals, comprising:
passing a solution of group III nitride and supercritical ammonia through a baffle region comprising a plurality of flow impediments, the flow impediments defining a flow path for the solution having a path-length that is greater than a path-length of a flow path parallel to a longitudinal axis of the baffle region; and
growing a group III nitride crystal in a crystal growth region.

31. The method of claim 30, wherein the plurality of flow impediments comprises a plurality of plates oriented transverse to the longitudinal axis of the baffle region,
the plurality of plates comprising a first plate having one or more openings and a second plate having one or more openings different than the one or more openings of the first plate.

32. The method of claim 31, wherein at least one of the one or more openings on the first plate are offset from the one or more openings on the second plate.

33. The method of claim 32, wherein the openings on the first plate are offset from the one or more openings on the second plate such that there is no linear flow path through the baffle region.

34. The method of claim 31, wherein at least one of the one or more openings on the first plate has a larger perimeter that the one or more openings on the second plate.

35. The method of claim 34, wherein the second plate comprises an opening that is longitudinally aligned with the larger perimeter opening on the first plate.

36. The method of claim 34, wherein the second plate comprises at least a second opening offset from the large perimeter opening on the first plate.

37. The method of claim 30, wherein the group III nitride crystal is grown at a growth rate of at least 100 μm/day.

38. The method of claim 30, wherein a total amount of group III nitride deposited on a wall of the reactor is suppressed to be less than 20% of a total consumption of the group III nutrient.

39. The method of claim 30, wherein the group III nitride crystal is grown on a group III nitride seed crystal.

40. The method of claim 30, wherein the group III nitride crystal is a GaN crystal.

41. The method of claim 40, wherein the GaN crystal has a full width half maximum value of X-ray rocking curve from 002 reflection less than 200 arcsec.

42. The method of claim 30, further comprising dissolving a group III nutrient material in the supercritical ammonia.

43. The method of claim 30, wherein the solution further comprises ions selected from the group consisting of Li⁺, Na⁺, K⁺, Ca²⁺, Mg²⁺, and mixtures of any thereof.

44. The method of claim 30, wherein the baffle region comprises a nickel alloy.

45. A reactor for growing group III nitride crystals comprising:
a high pressure ammonothermal reactor vessel;
a source dissolution region configured to contain a group III nutrient material;
a crystal growth region configured to contain at least one group III nitride seed crystal; and
a baffle region between the source dissolution region and the crystal growth region, the baffle region comprising
a plurality of plates oriented transverse to a flow comprising a group III nitride and supercritical ammonia from the source dissolution region to the crystal growth region, the plurality of plates comprising a first plate having one or more openings and a second plate having one or more openings different than the one or more openings of the first plate.

46. The reactor of claim 45, wherein the one or more openings on the first plate are offset from the one or more openings on the second plate.

47. The reactor of claim 46, wherein the openings on the first plate are offset from the one or more openings on the second plate such that there is no linear flow path through the baffle region.

48. The reactor of claim 45, wherein at least one of the one or more openings on the first plate has a larger perimeter than the one or more openings on the second plate.

49. The reactor of claim 48, wherein the second plate comprises an opening that is longitudinally aligned with the larger perimeter opening on the first plate.

50. The reactor of claim 48, wherein the second plate comprises at least a second opening offset from the large perimeter opening on the first plate.

51. The reactor of claim 45, wherein each plate is separated from an adjacent plate by at least 1 mm.

52. The reactor of claim 45, wherein the group III nitride crystals are GaN crystals.

53. The reactor of claim 45, wherein the plates are made of a nickel alloy.
